(19) United States
(12) Patent Application Publication
(10) Pub. No.: US 2006/0137969 A1
(43) Pub. Date: Jun. 29, 2006

(54) Method of manufacturing alloy sputtering targets

(76) Inventors: Gerald B. Feldewerth, Beaverton, OR (US); John P. Barnak, Newberg, OR (US); Michael Goldstein, Sunnyvale, CA (US)

Correspondence Address: INTEL/BLAKELY, 12400 WILSHIRE BOULEVARD, SEVENTH FLOOR, LOS ANGELES, CA, 90025-1030, US

(21) Appl. No.: 11/026,644

(22) Filed: Dec. 29, 2004

(51) Int. Cl. C23C 14/00

(52) U.S. Cl. 204/192.15; 204/298.12

(57) ABSTRACT

The present invention relates to a composite sputtering target comprising a plurality of bonded metal pieces. The composite sputtering target further comprises a bonded region between the metal pieces. The bonded region may comprise an inter-metallic region upon bonding. The composite sputter target of the present invention may be used in conjunction with an apparatus for sputtering alloy films on substrates.

### BACKGROUND

1. Field

The present invention relates to the field of semiconductor manufacturing, specifically a composite sputter target for depositing alloy films on semiconductor substrates.

2. Description of Related Art

Sputtering is a semiconductor manufacturing process used to deposit pure metal or alloy films on substrates for semiconductor process applications such as vias, plugs, and metal recesses. Sputtering may also be used for advanced applications such as salicide deposition, tungsten adhesion, Ta/TaN barrier, Cu seed, C4 metallization, and backside metallization. Currently, sputtering is accomplished by the use of sputtering targets, whereby ions are attracted to the sputtering target at a force that disassociate metal atoms from the target unto a substrate.

Manufacturing sputter targets conventionally involves a molten metal casting and thermo-mechanical processing (TMP) manufacturing process. However, some materials melt at a very high temperature and can not be easily cast. Other materials are very brittle and can not survive the TMP process without cracking or breaking. These materials which can not be easily casted or survive the TMP process normally require a powder metallurgy manufacturing process.

Powder metallurgy involves consolidating elemental or pre-alloy powders. However, consolidating some metal powders for manufacturing bimetallic sputter targets may result in arcing, in-film defects, brittleness, high porosity, and higher impurity levels which are undesirable for sputtering high quality metal films.

### BRIEF DESCRIPTION OF THE DRAWINGS

FIG. 1 is an illustration of sputter target 100 according to an embodiment of the present invention.

FIG. 2 is an illustration of an embodiment of the present invention featuring rectangular shaped metal pieces.

FIG. 3 is an illustration of an embodiment of the present invention featuring circular, concentric shaped metal pieces.

FIGS. 4A-4E are illustrations of an embodiment for manufacturing a sputter target of the present invention.

FIG. 5 is a flowchart of an embodiment for manufacturing a sputter target of the present invention.

FIG. 6 is an illustration of a conventional sputter apparatus utilizing a sputter target to sputter deposit metal films.

FIG. 7 is a cross-sectional illustration of a substrate by which a metal film can be sputter deposited using a sputter target of the present invention.

### DETAILED DESCRIPTION OF THE PRESENT INVENTION

The present invention is a composite sputter target comprised of a plurality of first metal pieces bonded to a plurality of second metal pieces. The sputter target may be used to sputter deposit alloy films of the first and second metals. For example, in order to form a sputter target to deposit a AlCu alloy film, a plurality of Al pieces are bonded to a plurality of Cu pieces. In one embodiment, the bonded first and second metal pieces form an inter-metallic compound between them, which has an elemental composition of both first and second metal pieces. The sputter target is ideal for sputter depositing inter-metallic compounds such as TiAl, which are generally too brittle to manufacture into sputter targets using normal casting and thermo-mechanical processes. By bonding individual metal pieces, a sputter target may be manufactured with high purity, low defect density, and void free targets by which high purity, void free films may be sputter deposited on a substrate.

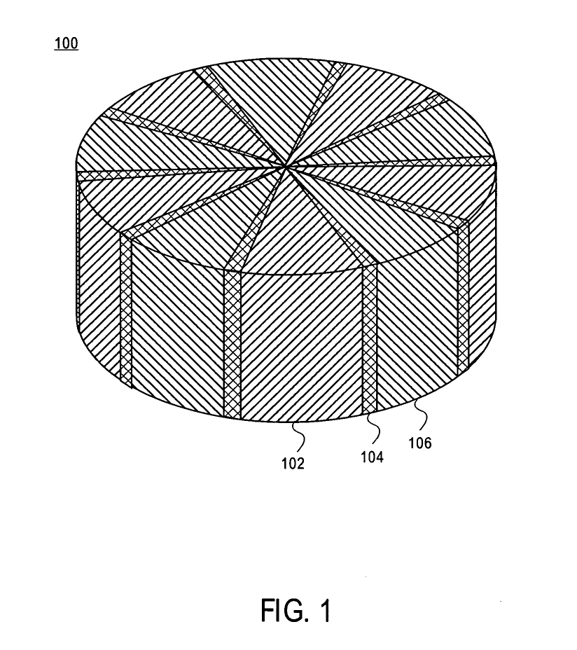

FIG. 1 illustrates an embodiment of a composite sputter target 100 in accordance with an embodiment of the present invention. As shown in FIG. 1, sputter target 100 is comprised of first metal X bonded to a second metal Y, which may be used to sputter deposit a XY alloy compound. A bonded region 104 is formed between first metal piece 102 and second metal piece 106. The bonded region 104 comprises an alloy (XY), which is formed by diffusing the first metal X into the second metal Y and/or diffusing the second metal Y into the first metal X. For example, sputter target 100 can comprise a plurality of Al first metal pieces 102 bonded to a plurality of Cu second metal pieces 106 to provide a composite target for sputtering AlCu alloy films. The sputter target is ideal for sputter depositing alloy films from metals such as, but not limited to Al—Cu, Ta—Cu, and Mo—Al.

In an embodiment of the present invention, the sputter target is formed from a plurality of first metal pieces, such as Al, and second metal pieces, such as Cu, which together form an inter-metallic compound, AlCu. Typically, sputter targets comprised of inter-metallic compounds are too brittle to enable the fabrication of a sputter target through powder metallurgy because the TMP process would cause the brittle alloys to crack or break. Accordingly, individual metal components that form inter-metallic compounds are bonded together, which can be easily processed by casting and TMP. By bonding individual components of the inter-metallic compound together, each of the segments of metal pieces remain ductile, enabling fabrication of a ductile target. In an embodiment of the present invention, the bonded region is sufficiently large to ensure each of the pieces are sufficiently bonded to one another, but is not too large that the target becomes brittle. In an embodiment the bonded region has a width on the order of microns. In an embodiment, the bonded region has a width in the range of 10-500 microns.

In the embodiment of FIG. 1, the quantity and size of first and second metal pieces comprising the sputter target 100 are manufactured to obtain the alloy concentration desired. For example, if an inter-metallic alloy consisting 60% Ti and 40% Al is desired, then the sputter target will typically comprise 60% Ti pieces and 40% Al pieces. Accordingly, if an alloy concentration with an equal ratio of first and second metals is desired, then the sputter target typically comprise 50% first metal pieces and 50% second metal pieces. In an embodiment, to achieve the concentration desired, the size of each metal piece is the same, but the quantity of each metal is apportioned in the sputter target such that there are more or less pieces of each metal. In another embodiment, each metal is manufactured to a size larger or smaller in proportion to one another to achieve the concentration desired.

Sputter target 100 may be used to sputter films of varying alloy content, but is generally used to sputter films with at least an alloy concentration greater than 10%. The size of the first and second metal pieces are manufactured to a size such that uniform distribution of the individual elements in the deposited film is achieved. Additionally, the first and second metal pieces are manufactured to a size small enough to achieve the desired elemental uniformity without compromising manufacturability. In an embodiment, the first and second metal pieces have an area of approximately 42 in² and a thickness of 0.5 inches. In an embodiment, metals are chosen according to the metal's respective sputter rate to achieve the desired alloy concentration for the sputtered film.

In an embodiment, a composite sputter target can be used to sputter deposit a tri-metallic alloy (XYZ) on a substrate. In an embodiment such composite sputter target comprises homogeneous metal pieces X, homogeneous metal pieces Y, and homogeneous metal pieces Z. Alternatively, composite sputter target may comprise of homogeneous metal pieces X and alloy metal pieces YZ. For example, a composite sputter target of the present invention may be comprised of Al, Cu, and Ti for sputter depositing an Al—Cu—Ti film.

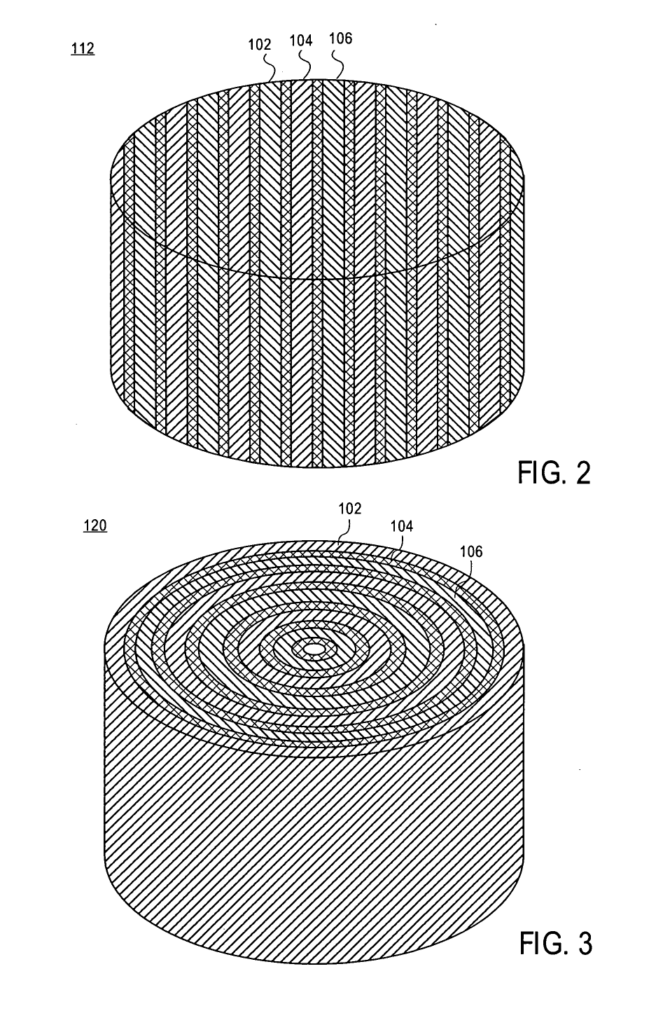

The first and second metal pieces of the sputter target 100 may be manufactured in a variety of shapes. For example, embodiments of the present invention may have various metal piece shapes such as pie-slice, circular, semi-circular, rectangular, semi-rectangular, triangular, and semi-triangular. In an embodiment, both first metal and second metal pieces are pie slice shaped as illustrated by first metal piece 102 and second metal piece 106 in FIG. 1. In an alternate embodiment, both first metal and second metal pieces are shaped in semi-rectangular slices as illustrated by first metal piece 102 and second metal piece 106 in FIG. 2. In another embodiment, both first metal and second metal pieces are shaped in circular, concentric pieces as illustrated by first metal piece 102 and second metal piece 106 in FIG. 3.

Sputter target 100 may be manufactured to a shape that is suitable for sputter deposition equipment. In an embodiment, sputter target 100 is manufactured into a round, planar shape as shown in FIG. 1. In an alternate embodiment, sputter target 100 may be manufactured into a contour shape to curtail the effects of target erosion patterning commonly known in the art. After subsequent processing, sputter target 100 will usually assume the signature bullseye shape from wear.

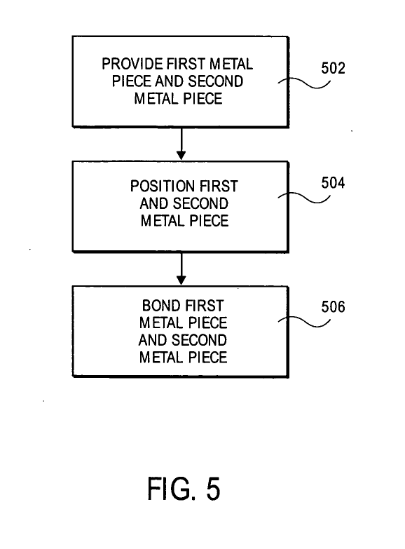

Sputter target 100 may be manufactured by any suitable process when the individual metal pieces can be adequately bonded together such as, but not limited to diffusion bonding. In an embodiment of the present invention, the composite sputter target 100 is formed by a Hot Isostatic Press (HIP) process as shown by the flowchart in FIG. 5. As illustrated in FIG. 5, providing first metal piece and second metal piece 502, positioning first and second metal piece 504, and bonding first metal piece and second metal piece 506 are cumulative steps involved in the HIP process.

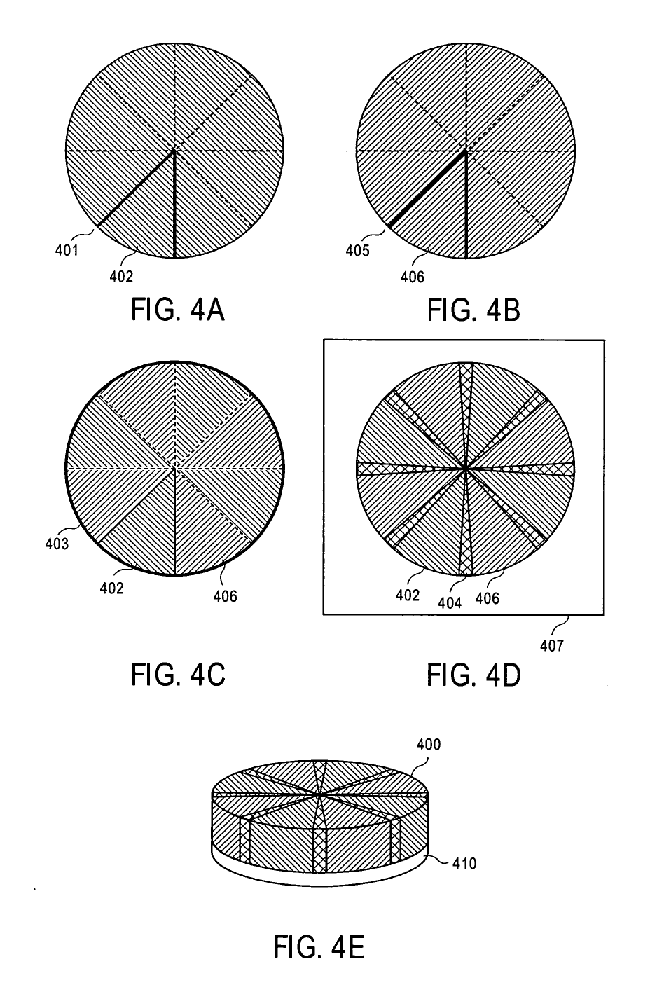

To manufacture sputter target 100 by a HIP process, first and second metal pieces must be provided. According to an embodiment of the present invention as illustrated in FIG. 4A-4E, first metal piece 402 and second metal piece 406 are provided from a source of each respective metal, which is to comprise the composite sputter target 100. In FIG. 4A and FIG. 4B first metal 401 and second metal 405 are illustrative of homogeneous solid metal sources. In an embodiment, first metal 401 and second metal 405 are formed by a casting and thermo-mechanical process. Individual metal pieces are cut from first metal 401 and second metal 405 as illustrated by first metal piece 402 and second metal piece 406 in FIG. 4A and FIG. 4B respectively.

Next, first metal piece 402 and second metal piece 406 are positioned for bonding. In an embodiment, first and second metal pieces are positioned one at a time in alignment can 403 until completely filled as shown in FIG. 4D. First metal piece 402 is aligned flush with second metal piece 406 to ensure adequate bonding within alignment can 403. In an embodiment, metal pieces can be arranged in alignment can 403 in an alternating fashion to achieve the alloy concentration of the sputtered film desired. Alignment can 403 is made out of stainless steel in the present embodiment, but can be made from any rigid materials which can withstand high temperature and pressure.

Next, first metal pieces and second metal pieces are bonded together by HIP process. Alignment can 403, containing first and second metal pieces, are placed within a Hot Isostatic Press chamber 407. Next, within Hot Isostatic Press chamber 407, process conditions are set for high temperature and high pressure to induce diffusion bonding of the first and second metal pieces. The temperature within Hot Isostatic Press chamber 407 is purposefully set below the melting point of each metal piece. Typically, the temperature is set in a range between 400-600° C. However, the temperature set within Hot Isostatic Press chamber 407 is dependent upon the composition of metals within the chamber. For example, if the first metal pieces and second metal pieces are made of titanium and aluminum respectively, chamber temperature must be set below 660° C. to avoid melting because the melting point of titanium and aluminum are 1660° C. and 660° C. respectively. The pressure is set within the chamber to form a good contact between the first metal pieces and second metal pieces to induce diffusion bonding. In an embodiment of the present invention, the pressure is approximately 10 atmospheres. In the embodiment of FIG. 4D, the first and second metal pieces remain in Hot Isostatic Press chamber 407 for the amount of time needed to ensure sufficient diffusion bonding between the plurality of first and second metal pieces to form bonded regions 404. In an embodiment of the present invention, the time needed for sufficient bonding is approximately thirty minutes.

In an embodiment of the present invention as illustrated in FIG. 4D, subsequent bonding occurs by diffusion of the first metal pieces into the second metal pieces and/or diffusing the second metal pieces into the first metal pieces. In an embodiment, the diffusion process forms bonded region 404 comprisded of an inter-metallic compound. The inter-metallic compound has an elemental composition of both first and second metal, but has a different crystal orientation than both first metal piece 402 and second metal piece 406. For example, if first metal piece 402 and second metal piece 406 are made from titanium and aluminum respectively, second metal piece 406 will diffuse into first metal piece 402 to form a TiAl inter-metallic compound consisting of both titanium and aluminum.

After diffusion bonding the first and second metal pieces in the HIP, a sputter target 400 according to the present invention is formed. FIG. 4E is an illustration of sputter target 400 formed by the HIP process mounted to backing plate 410. In an embodiment, sputter target 400 is mounted to backing plate 410 for use in a sputtering apparatus. In an embodiment, the size of backing plate 410 is 22 inches in diameter and 0.5 inches thick for which an 18 inch diameter, 0.5 inch thick sputter target 400 is mounted.

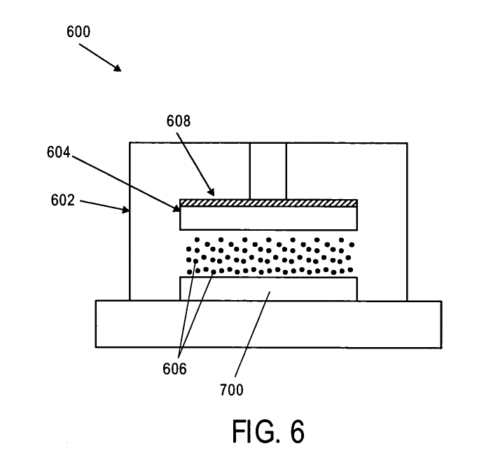

The sputter target of the present invention can be used within a sputtering apparatus such as sputter apparatus 600 illustrated in FIG. 6. Sputtering apparatus 600 is comprised of vacuum chamber 602, sputter target 604, and backing plate 608. Sputter target 604 may be used within a sputtering apparatus to sputter metal 606 as alloy films on a substrate as illustrated by the substrate 700 in FIG. 6. The sputtered alloy films can be used in many semiconductor applications such as forming barrier layers, capping layers, metal interconnect layers, metal electrodes such as capacitor electrodes and gate electrodes, and ball limiting metallurgy (BLM).

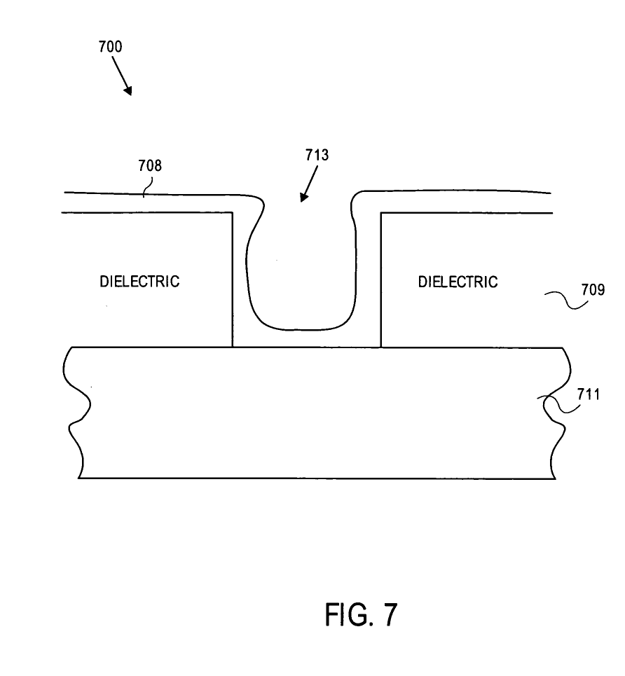

Sputter target 100 may be used to sputter high purity, void free metal films on a substrate for a variety of semiconductor process applications such as, but not limited to vias, plugs, and metal recesses. For example, sputter target 100 may be manufactured to sputter deposit a high purity, void free TiAl film on a substrate to form a metal via. In an embodiment, substrate 700 may comprise a semiconductor substrate 711, dielectric 709, and opening 713 whereby sputtered alloy film 708 is formed in opening 713 as shown in FIG. 7.

1. A sputtering target comprising:
a first metal piece and a second metal piece, wherein said
first metal piece is bonded to said second metal piece.

2. The sputtering target of claim 1, wherein the shape of said sputtering target is round and flat.

3. The sputtering target of claim 1, wherein the shape of said metal pieces is selected from the group consisting of pie sliced, circular, semi-circular, rectangular, semi-rectangular, triangular, and semi-triangular.

4. The sputtering target of claim 1, wherein said bonded region comprises an inter-metallic compound.

5. The sputtering target of claim 4, wherein dimensions of said inter-metallic compound is on the order of microns.

6. The sputtering target of claim 1, wherein said first metal piece has a different metallic composition than said second metal piece.

7. The sputtering target of claim 6, wherein the composition of said first metal piece and said second metal piece are selected from the group consisting of pure metal and alloy material.

8. The sputtering target of claim 7, wherein said
first metal piece and said second metal piece are selected from the group consisting of Al, Cu, Cu alloy, Mo, Ta, Ti, and W.

9. A sputtering apparatus comprising:
a vacuum chamber comprising:
a magnet assembly above the substrate,
a sputtering target under said magnet assembly, wherein said
sputtering target is comprised of a bonded first metal piece and a second metal piece.

10. The sputtering apparatus of claim 9, wherein said first metal piece and said second metal piece are ductile materials.

11. A method of forming a sputtering target comprising:
forming a first metal piece and a second metal piece;
bonding said first metal piece and said second metal piece;
forming a bonded region between said first metal piece and said second metal piece.

12. The method of claim 11, wherein said bonding is Hot Isostatic Press.

13. The method of claim 11, wherein
said sputtering target is placed within a sputtering apparatus;
said sputtering target is bombarded with ions thereby
forming thin films in openings of microelectronic devices.

14. The method of claim 13, wherein said openings are selected from the group consisting of vias, plugs, and metal recesses.

15. The method of forming a sputtering target comprising:
forming a first metal piece and a second metal piece;
containing said first metal piece and said second metal piece in a metal container;
placing said metal container containing said first metal piece and said second metal piece in an enclosure;
heating said enclosure at a temperature less than the melting temperatures of said first metal piece and said second metal piece;
pressurizing said enclosure to form a good contact between said first metal piece and said second metal piece;
bonding said first metal piece and said second metal piece into a bond within said enclosure, wherein said bonding occurs by diffusion of said first metal piece into said second metal piece or diffusion of said second metal piece into said first metal piece;
removing bonded said first metal piece and said second metal piece from enclosure and said container.

16. The method of claim 15, wherein composition of said metal container is stainless steel.

17. The method of claim 15, wherein said enclosure is a Hot Isostatic Pressure chamber.

18. A method of sputtering comprising:
inserting a sputtering target into a sputtering apparatus, wherein said
sputtering target comprises a bonded first metal piece and a second metal piece;
sputtering said sputtering target to form thin layers.

19. The method of claim 18, wherein said thin layers have a minimum alloy content of ten percent.

20. The method of claim 18, wherein said thin layer is an inter-metallic.
